(19) United States
(12) Patent Application Publication
(10) Pub. No.: US 2009/0133732 A1
(43) Pub. Date: May 28, 2009

(54) Floating solar power collectors and application means

(76) Inventors: Chih-Yu Hsia, Arcadia, CA (US); Michael Jonathan Hsia, Arcadia, CA (US); Patricia Shirley Hsia, Arcadia, CA (US)

Correspondence Address: Chih-Yu Hsia, 301 Warren Way, Arcadia, CA, 91007, US

(21) Appl. No.: 11/986,745

(22) Filed: Nov. 26, 2007

(51) Int. Cl. H01L 35/00

(52) U.S. Cl. 136/206; 174/110 R

(57) ABSTRACT

A floating power station which can be stationary or movable with a solar power ship assembly which consists an power boat, a tow cable, a tow cable keeper, and many floating solar power stations which are towed or self-propelling and which consist many optional floating cable boxes and floating solar power collection units and which have solar panel arrays and flexible container to equalize air pressures; the power boat being an electrical powered boat which has a propelling system which can propel the solar power ship assembly; the tow cable keeper being a towed float which can keep one end of the tow cable above water; the tow cable being a link system which connects the tow cable keeper with the power boat; electricity collected by the floating solar power station being able to be sent to the power boat by the power conveying mean of the floating solar power station.

### BACKGROUND OF THE INVENTION

1. Field of the Invention

This invention relates to solar power collectors and particularly to solar power collectors that float on water and means to use them.

2. Descriptions of the Prior Arts

No prior art related to floating solar power collectors and application means was found.

### SUMMARY OF THE INVENTION

Solar power panel arrays produce renewable power but they need spaces and supports when they are used on land. The land and supports are costly. Normally there are not enough spaces for the solar power panel arrays to be installed on a ship to power the ship. Further, moisture may damage the solar power panel arrays when they are being used on water or water related crafts. Therefore, means that will not need land nor costly supports and that can power ships with electricity from solar power panel arrays are being sought.

The current invention provides means to create watertight enclosures and accessories for solar power panel arrays so that they can float on water surfaces and they do not need lands or special costly supports. This invention introduces ways to create a large solar power station so that meaningful electricity can be generated. This invention also provides means to use the solar power stations so that electricity can be used in cargo transportation.

These and other objects and advantages of the invention, as well as the details of an illustrative embodiment, will be more fully understood from the following specification and drawings, in which:

### DRAWING DESCRIPTION

FIG. 1 is an isometric view of a floating solar power collector unit.

FIG. 2 is a top view of the device shown in FIG. 1.

FIG. 3 is a sectional view of the device shown in FIG. 2.

FIG. 4 is a top view of a floating base for the floating solar power collector unit shown in FIG. 1.

FIG. 5 is a sectional view of the device shown in FIG. 4.

FIG. 6 is a top view of a solar panel housing for the floating solar power collector unit shown in FIG. 1.

FIG. 7 is a sectional view of the device shown in FIG. 6.

FIG. 8 and FIG. 9 are a top view and a sectional view, respectively, of a pressure equalization device that is in the device shown in FIG. 1.

FIG. 10 is an isometric view of a floating cable box unit.

FIG. 11 is a top view of the device shown in FIG. 10.

FIG. 12 is a sectional view of the device shown in FIG. 11.

FIG. 13 is a top view of a floating base for the floating cable box unit shown in FIG. 10.

FIG. 14 is a sectional view of the device shown in FIG. 13.

FIG. 15 is a top view of a floating cable housing for the floating cable box unit shown in FIG. 10.

FIG. 16 is a sectional view of the device shown in FIG. 15.

FIG. 17 is an isometric view of a floating linker A unit.

FIG. 18 is a top view of the device shown in FIG. 17.

FIG. 19 is an elevation view of a floating linker B unit.

FIG. 20 is a sectional view of the device shown in FIG. 19.

FIG. 21 is an elevation view of a linker pin.

FIG. 22 is a sectional view of the device shown in FIG. 21.

FIG. 23 is an elevation view which illustrates the linking of the linker units with the linker pins shown in FIG. 21.

FIG. 24 is an isometric view which illustrate a floatable power cable.

FIG. 25 and FIG. 26 are isometric views which illustrate the uses of the invented devices in relatively stationary manners.

FIG. 27 is an isometric view which illustrate a self-propelling solar boat unit.

FIG. 28 is a plan view which illustrate the uses of the self-propelling solar boat unit shown in FIG. 27.

FIG. 29 is an isometric view which illustrate a towed solar boat unit.

FIG. 30 is a plan view which illustrate the uses of the towed solar boat unit shown in FIG. 29.

### GENERAL DESCRIPTION

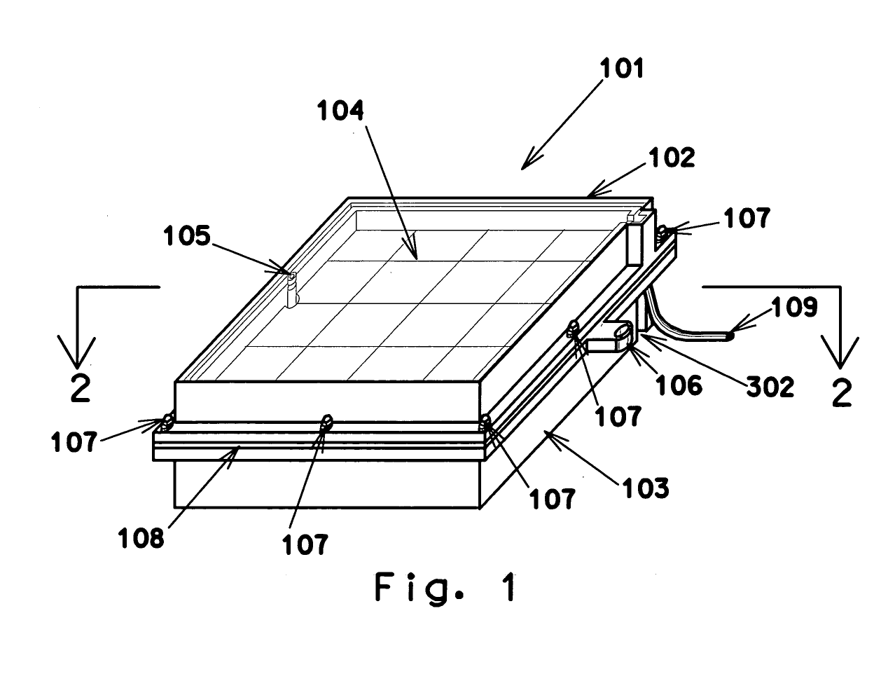

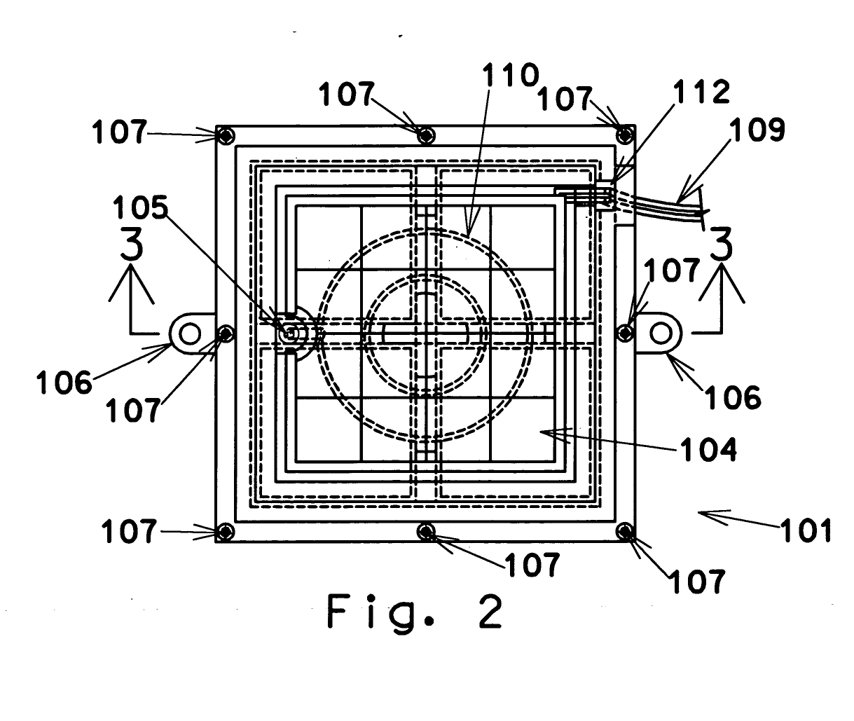

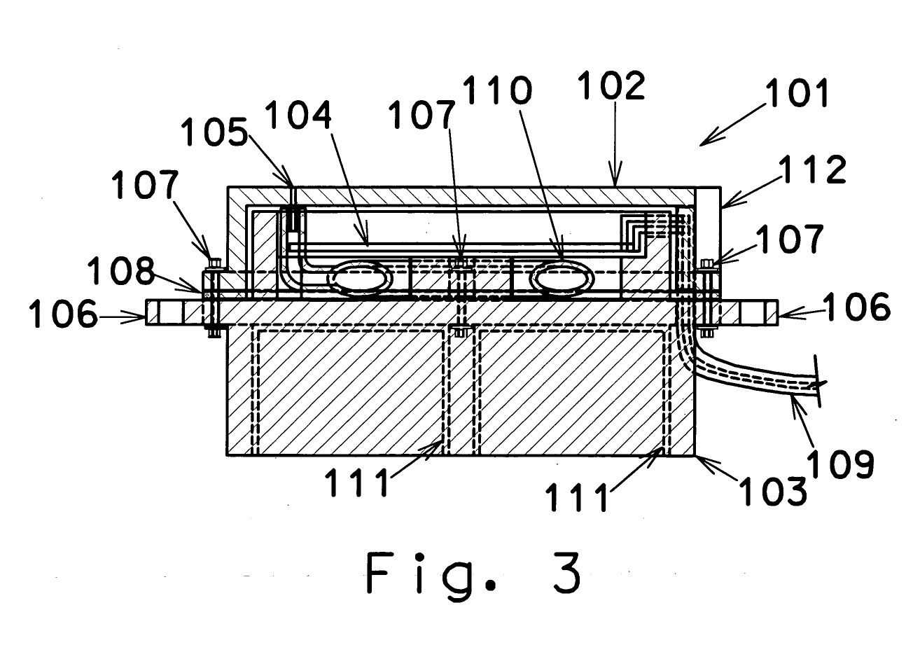

Referring to FIGS. 1 through 9, a floating solar power collection unit 101 consists a solar panel housing 102, a floating base 103, a solar power panel 104, a pressure equalization device 110, some vapor stoppers 108, many fastening devices 107, and a cable 109.

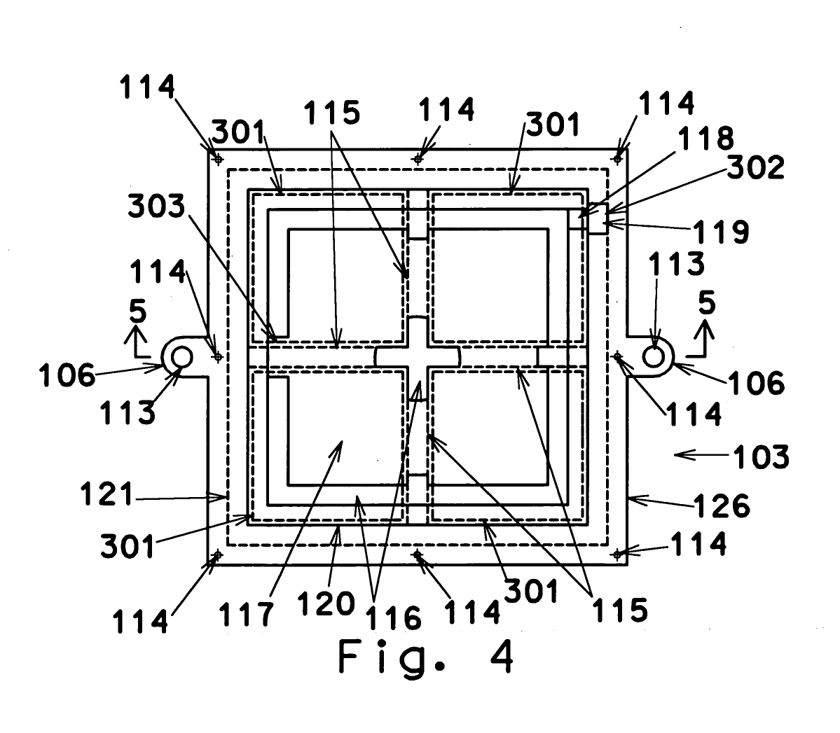

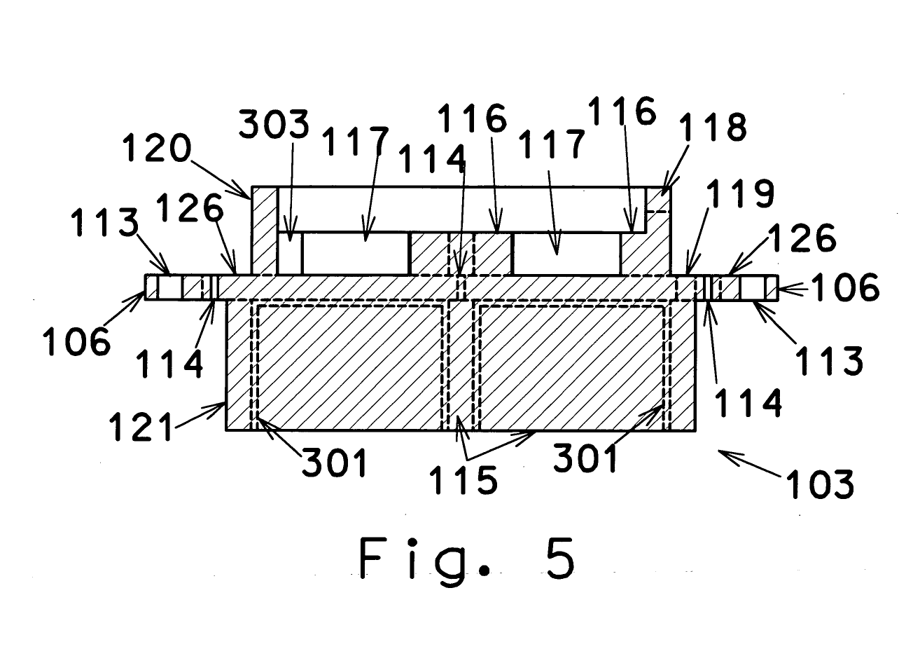

Referring to FIGS. 4 and 5, a floating base 103 consists a floating base plate 126, an upper wall 120, a lower wall 121, many solar power panel supports 116, many optional ribs 115, and at least one float 301 (4 shown). The floating base plate is a plate which has the upper wall and the solar power panel supports protruding from one surface; and the lower wall and the optional ribs protruding from the other surface. The upper wall and the lower wall are enclosure walls. The solar power panel supports are short walls which not only provide supports to a solar power panel but also create rooms, the pressure equalization device housing 117, for the pressure equalization device which will be described later. The solar power panel support has the pressure equalization tube connector break 303 which is a slot on the short walls. The optional ribs are walls which increase the rigidity of the floating base plate. The upper wall has a cable outlet cut 118 which is a recessed area on a rim of the upper wall. The lower wall has a cable outlet slot 302 which is a slot on the lower wall. The floating base plate has a cable outlet 119 which is a slot on the plate. The cable outlet cut 118, the cable outlet 119 and the cable outlet slot 302 are so lined that a cable can pass through them. The floating base plate has many fastener holes 114 which are holes scattered along the edges of the plate. The base plate has at least one connecting device 106 (two shown) which is an eye on an edge of the plate. The float 301 is made of any floatable materials such as plastic foams. The float is mounted on the lower wall and/or between the lower wall and the ribs.

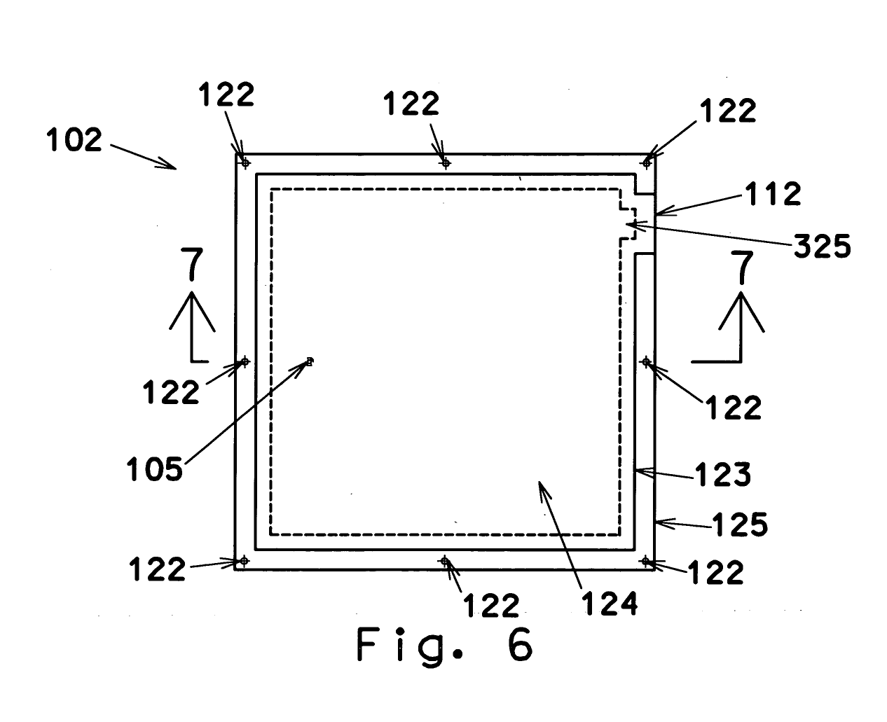

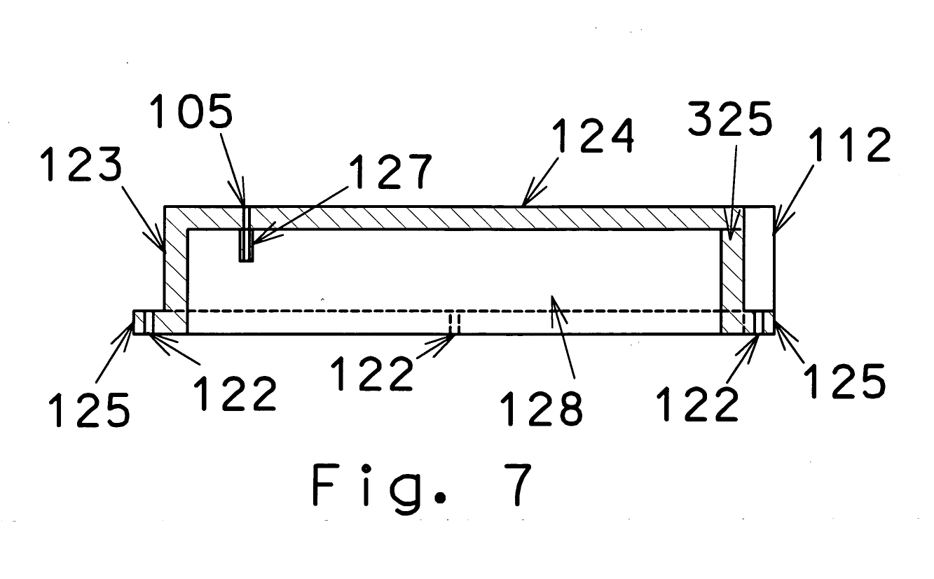

Referring to FIGS. 6 and 7, a solar panel housing 102 resembles an upside down bucket which has a wall 123 and a transparent top (or bottom when it is viewed as a bucket), the solar power panel roof 124. The interior of the solar panel housing has a space, the solar power panel space 128. A hole, the vent 105, is on the solar power panel roof. A vent connector 127 which protrudes toward the rim of the solar panel housing has a center hole which connects with the vent 105. There are many holes, the fastener holes 122 on the edge 125 of the solar panel housing. On the wall of the solar panel housing, there is a protruding area, the cable outlet housing 112, which provide a space, the cable outlet opening 325, for the cable.

Referring to FIGS. 1, 2 and 3, the solar power panel 104 can convert solar power into electricity. The cable 109 is an insolated electrical conductor which connects with the solar power panel and which conveys out electricity generated by the solar power panel. The vapor stoppers 108 are gaskets and water stop foams. The fastening devices are bolts, nuts and washers.

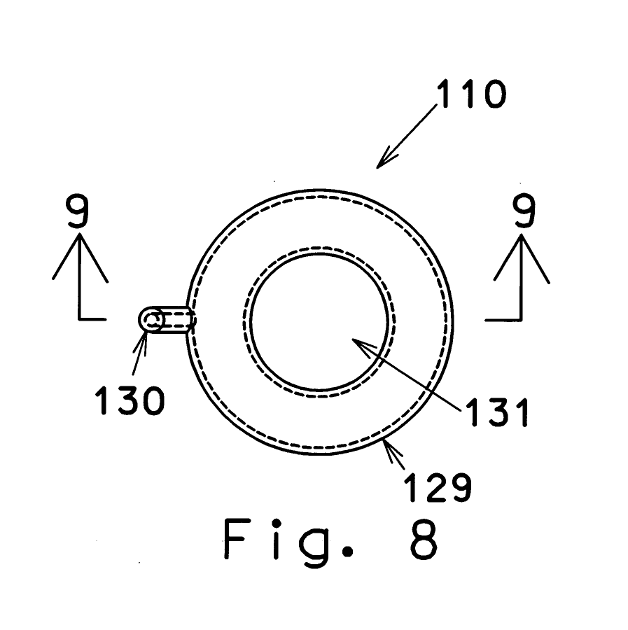

Referring to FIGS. 8 and 9, a pressure equalization device 110 consists a pressure equalization tube 129 and a pressure equalization tube connector 130. The pressure equalization tube is a hollow tube of suitable shape although a donut shape is shown. The pressure equalization tube is made of any flexible watertight material. The pressure equalization tube connector is another tube which one end connects with the pressure equalization tube.

To construct a floating solar power collection unit 101, a pressure equalization device 110 will be put into the pressure equalization device housing 117 of a floating base 103. The pressure equalization tube connector 130 will be placed in the pressure equalization tube connector break 303. A solar power panel 104 which has a connected cable 109 will be placed on top of the solar power panel supports 116. The cable will be routed through the cable outlet cut 118 and the cable outlet 119 toward the cable outlet slot 302. Then, a vapor stopper 108, most likely a gasket, will be placed on the edges of the floating base plate 126. Then, the vent connector 127 of the solar panel housing 102 will be inserted and connected to the end of the pressure equalization tube connector 130. The solar panel housing 102 will be placed on top of the floating base 103 with the cable outlet opening 325 over a portion of the cable 109. The fastening devices 107 will be inserted through the fastener holes 114 and 122 of the floating base 103 and the solar panel housing 102, respectively. The fastening devices will be tightened to clamp the floating base, the vapor stopper and the solar panel housing together. The voids in the cable outlet opening 325 between the cable, the upper wall 120 of the floating base and the wall 123 of the solar panel housing will be grouted with vapor stopper, a foam for this case, through the cable outlet 119. A watertight floating solar power collection unit 101 is then constructed.

Under the sun, the solar power panel will generate electricity. Meanwhile the air enclosed inside a floating solar power collection unit will heat up and expand. The expanded air will compress the pressure equalization tube 129 of the pressure equalization device 110. Some air will be expelled though the vent 105 to prevent the air pressure from building up inside the floating solar power collection unit. When the sun is out, the air inside the floating solar power collection unit is cooled and contracted. Some air will flow back into the pressure equalization tube to prevent vacuum in the floating solar power collection unit. Because the pressure equalization device is made of watertight material, no moisture will enter into the solar power panel space 128 of the solar power collection unit. The solar power panel inside the solar power collection unit is therefore protected from being damaged by moisture. Meanwhile, the integrity of the solar power collection unit will not be deteriorated by the cycles of the air pressure changes inside.

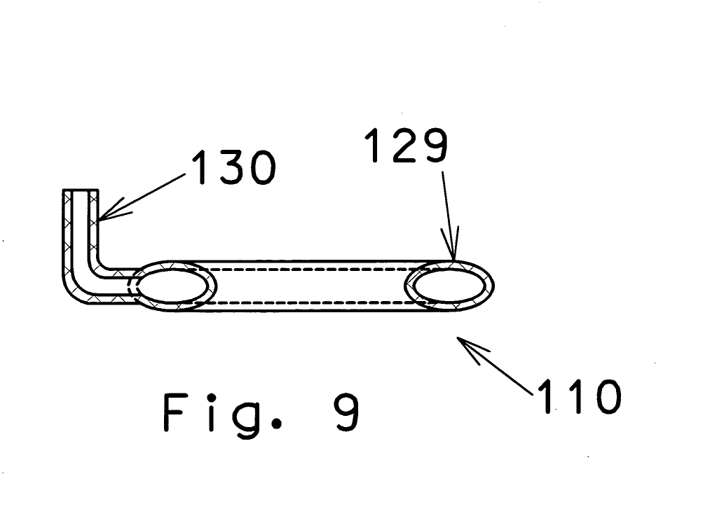

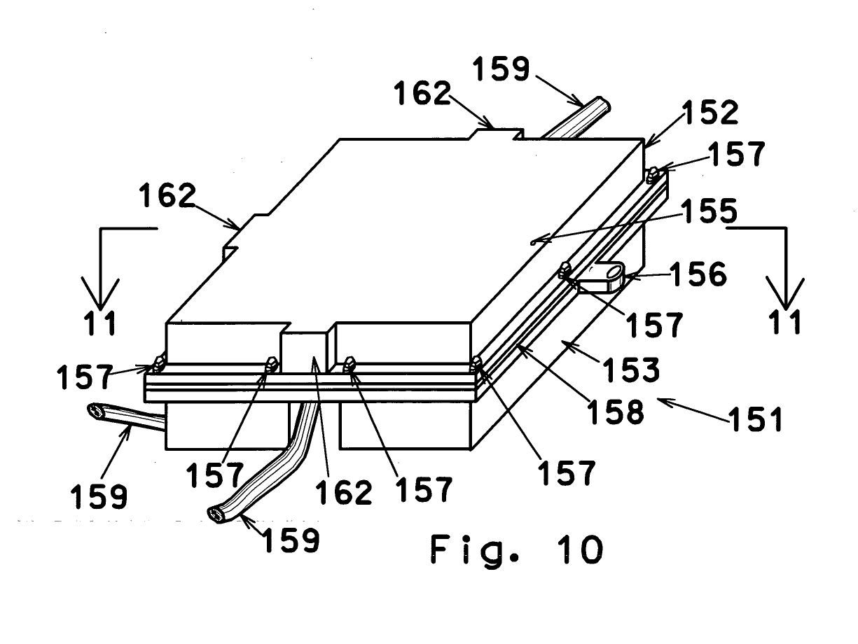

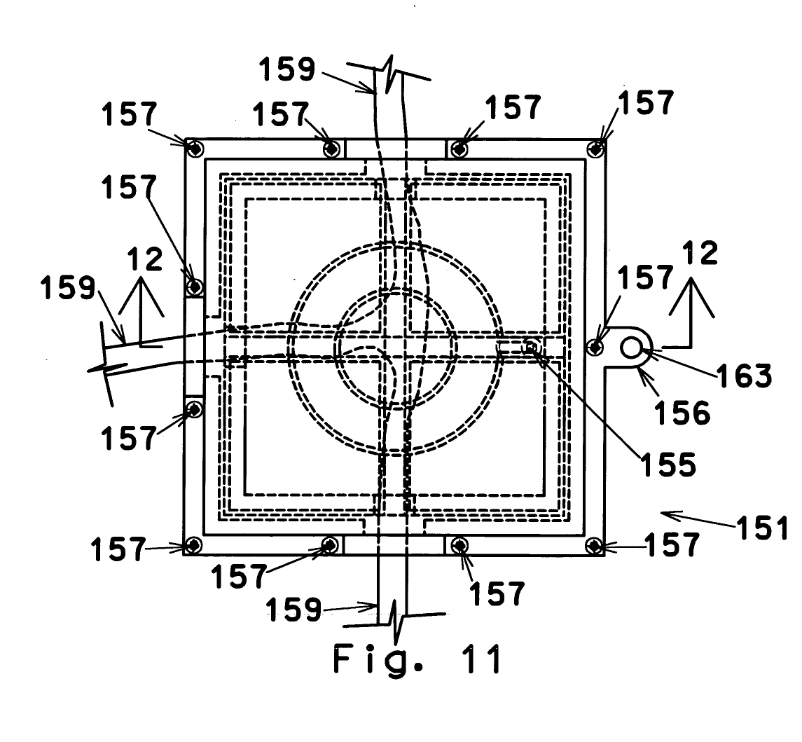

Referring to FIGS. 10 through 16, a floating cable box unit 151 consists a floating cable housing 152, a floating base 153, a pressure equalization device 160, some vapor stoppers 158, many fastening devices 157, and many cables 159.

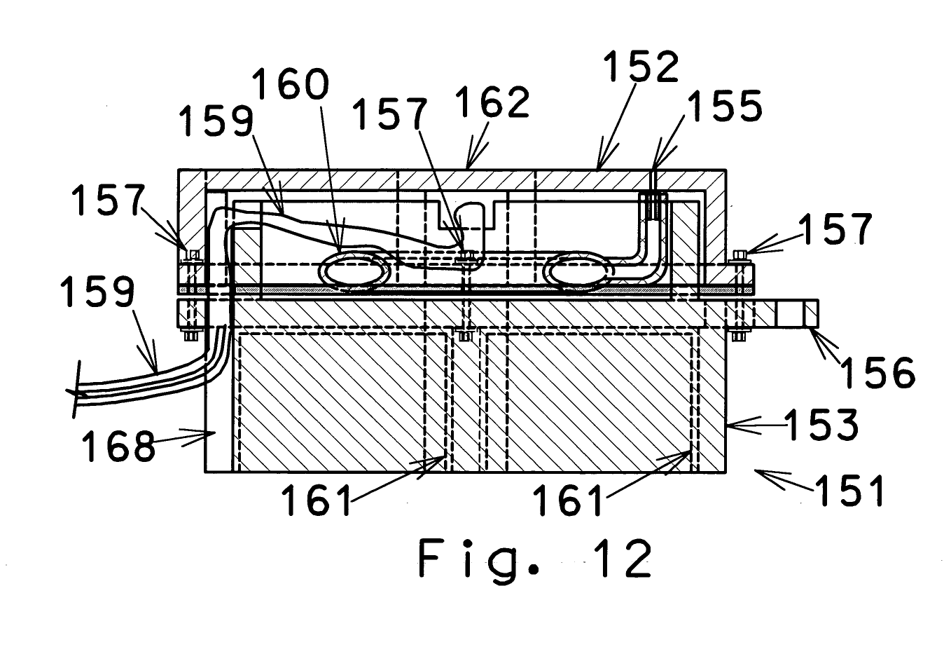

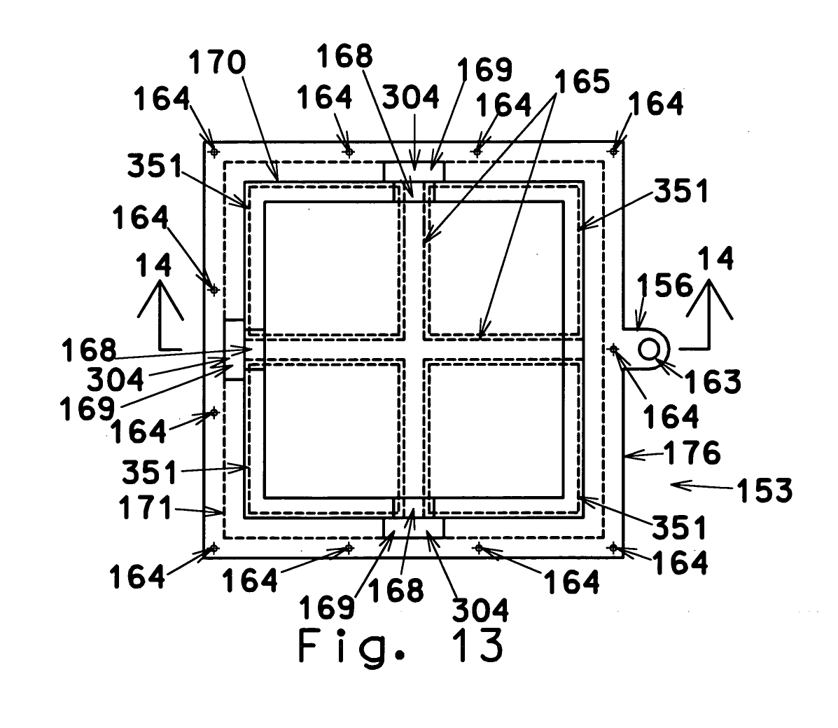

Referring to FIGS. 13 and 14, a floating base 153 consists a floating base plate 176, an upper wall 170, a lower wall 171, many optional ribs 165, and at least one float 351 (4 shown). The floating base plate is a plate which has the upper wall protruding from one surface; and the lower wall and the optional ribs protruding from the other surface. The upper wall and the lower wall are enclosure walls. The pressure equalization device 160, which is the same as the previously described pressure equalization device 110, will in the space enclosed by the upper wall. The optional ribs are walls which increase the rigidity of the floating base plate. The upper wall has at least three cable outlet cuts 168 which are recessed areas on the rim of the upper wall. The lower wall has at least three cable outlet slots 169 which are slots on the lower wall. The floating base plate has at least three cable outlets 304 which are slots on the plate. The cable outlet cut 168, the cable outlet 169 and the cable outlet slot 304 are so lined that a cable can pass through them. The floating base plate has many fastener holes 164 which are holes scattered along the edges of the plate. The base plate has at least one connecting device 156 which is an eye on an edge of the plate. The float 351 is made of any floatable materials such as plastic foams. The float is mounted on the lower wall and/or between the lower wall and the ribs.

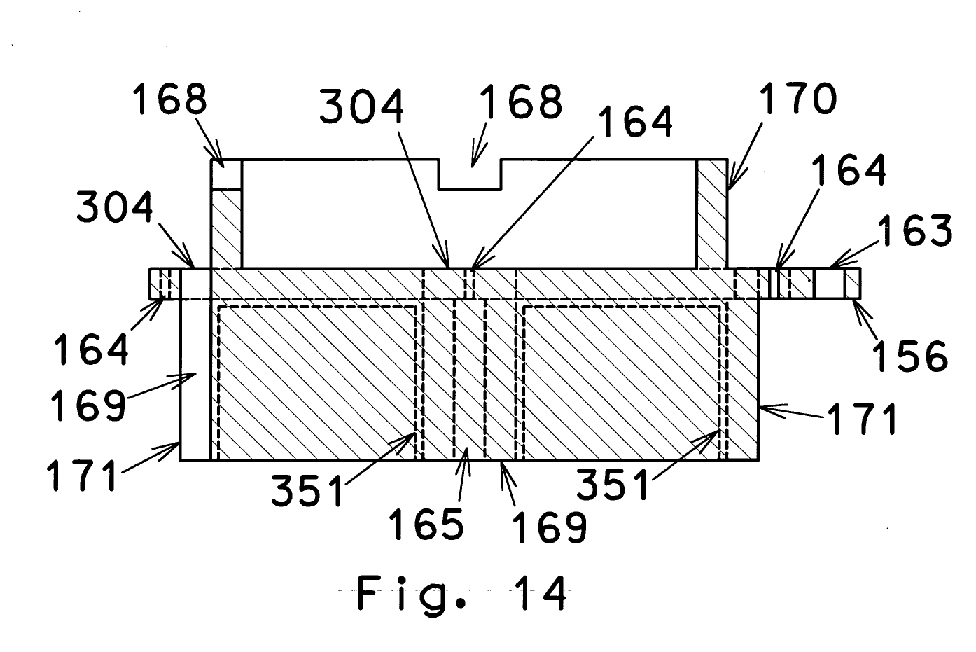

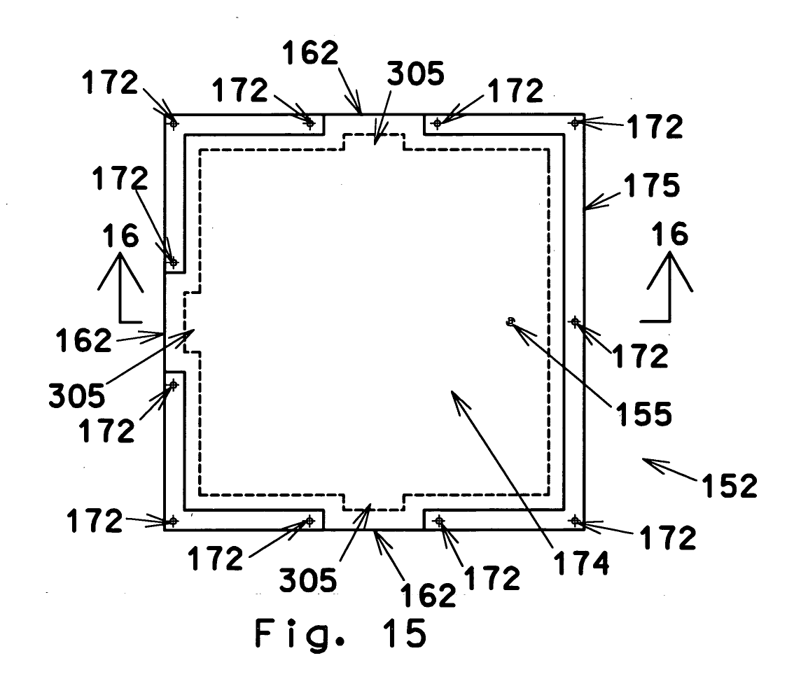

Referring to FIGS. 15 and 16, a floating cable housing 152 resembles an upside down bucket which has a wall 173 and a top (or bottom when it is viewed as a bucket), the floating cable housing roof 174. The interior of the floating cable housing has a space, the floating cable space 178. A hole, the vent 155, is on the floating cable housing roof. A vent connector 177 which protrudes toward the rim of the solar panel housing has a center hole which connects with the vent 155. There are many holes, the fastener holes 172 on the edge 175 of the solar panel housing. On the wall of the floating cable housing, there are at least three protruding areas, the cable outlet housings 162, which each provide a space, the cable outlet opening 305, for the cable.

Each of the cable 159 is an electrical conductor which connects with other cables inside the floating cable space 178. The vapor stoppers 158 are gaskets and water stop foams. The fastening devices are bolts, nuts and washers.

To construct a floating cable box unit 151, a pressure equalization device 160 will be put into the upper wall 170 of the floating base 153. One end of each of the cables will be spliced together. The cables will be routed through the cable outlet cuts 168 and the cable outlet 169 toward the cable outlet slot 304. Then, a vapor stopper 158, most likely a gasket, will be placed on the edges of the floating base plate 176. Then, the vent connector 177 of the floating cable housing will be inserted and connected to the end of the pressure equalization tube connector 130. The floating cable housing 152 will be placed on top of the floating base 153 with the cable outlet opening 305 over a portion of the cable 159. The fastening devices 157 will be inserted through the fastener holes 164 and 172 of the floating base 153 and the floating cable housing 152, respectively. The fastening devices will be tightened to clamp the floating base, the vapor stopper and the floating cable housing together. The voids in the cable outlet opening 305 between the cable, the upper wall 170 of the floating base and the wall 173 of the floating cable housing will be grouted with the vapor stopper, a foam for this case, through the cable outlet 169. A watertight floating cable box unit 151 is then constructed. The entire voids in the floating cable box unit may be grouted with the vapor stopper when the pressure equalization device is not used. The function of the pressure equalization device for the floating cable box unit is the same as that for the floating solar power collection unit described early.

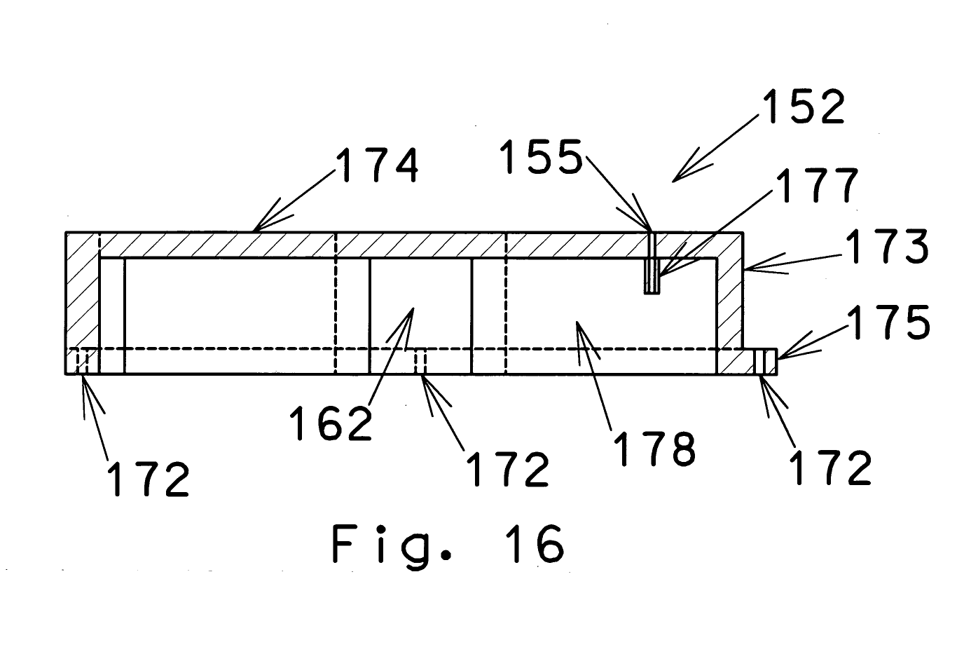

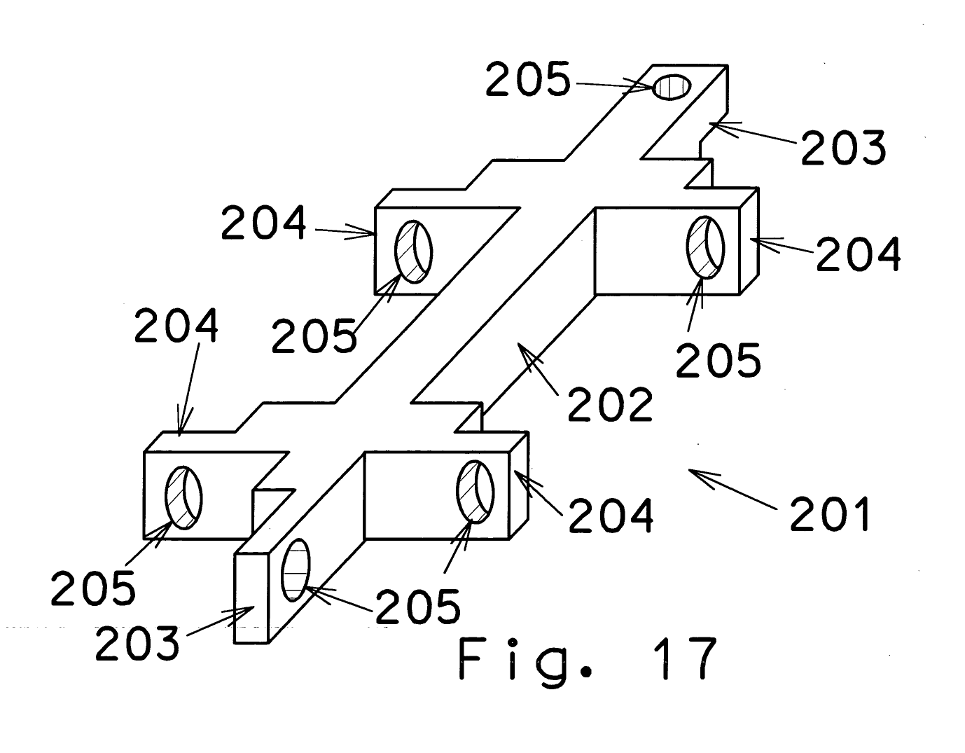

Referring to FIG. 17 and FIG. 18, a floating linker A unit 201 consists a stem 202, two end connectors 203 and at least one side connector 204 (four shown). The connectors are connected to the stem. All of the connectors are basically eyes. An eye of a connector may optionally have a coiled spring housing ring 207 and a coiled spring end slot 206. The coiled spring housing ring is a recessed area around the center of the eye. The coiled spring end slot is a slot in which an end of a coiled spring can be placed to limit the rotation of the coiled spring. A main body of a coiled spring can be placed inside the coiled spring housing. A floating linker A unit is made of floatable material such as plastic.

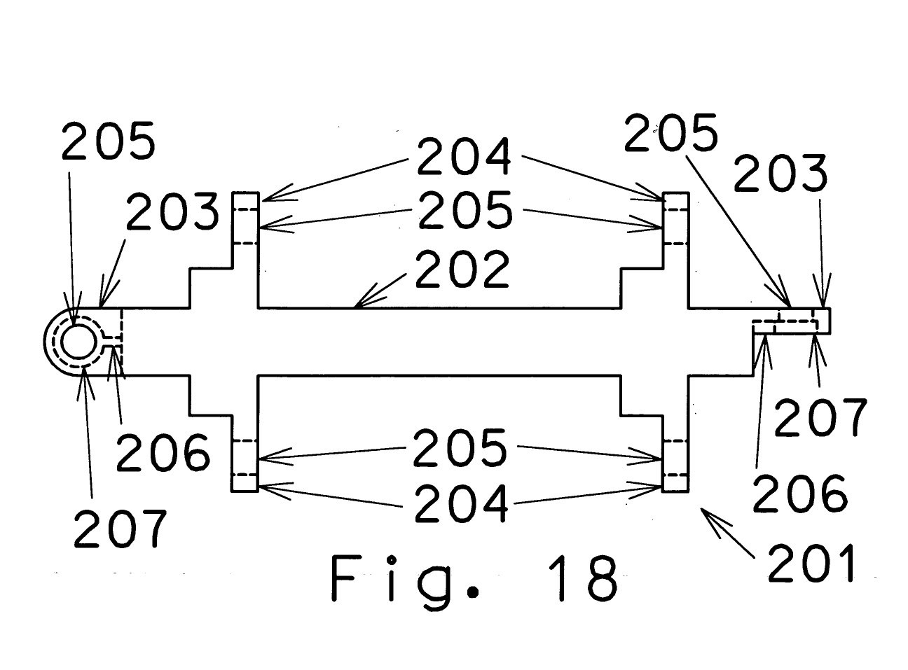

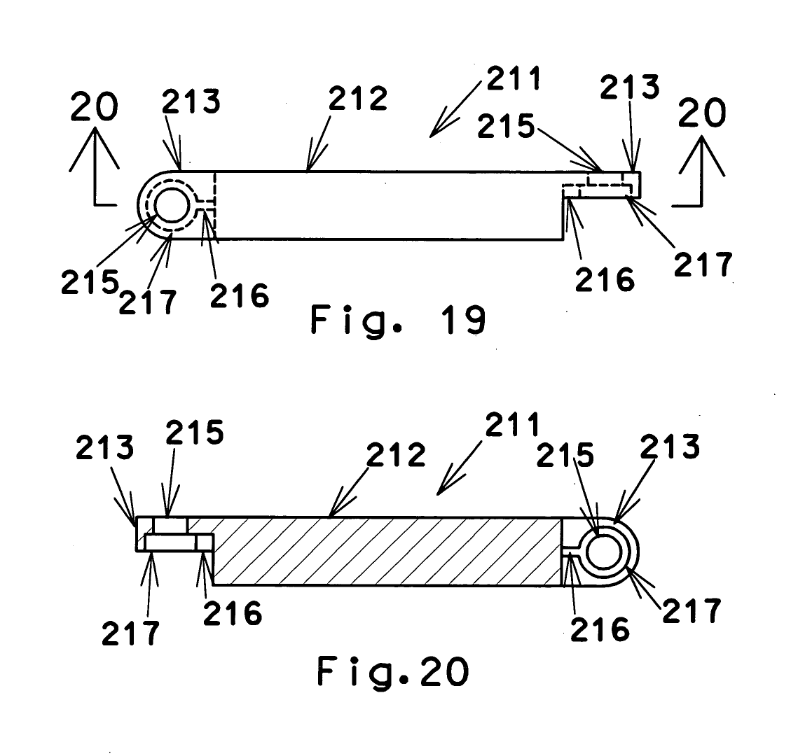

Referring to FIG. 19 and FIG. 20, a floating linker B unit 211 consists a stem 212 and two end connectors 213. The end connectors are basically eyes at the end of the stem. An eye of a connector may optionally have a coiled spring housing ring 217 and a coiled spring end slot 216. The coiled spring housing ring is a recessed area around the eye. The coiled spring end slot is a slot in which an end of a coiled spring can be placed to limit the rotation of the coiled spring. A portion of a coiled spring can be placed inside the coiled spring housing. A floating linker B unit is made of floatable material such as plastic.

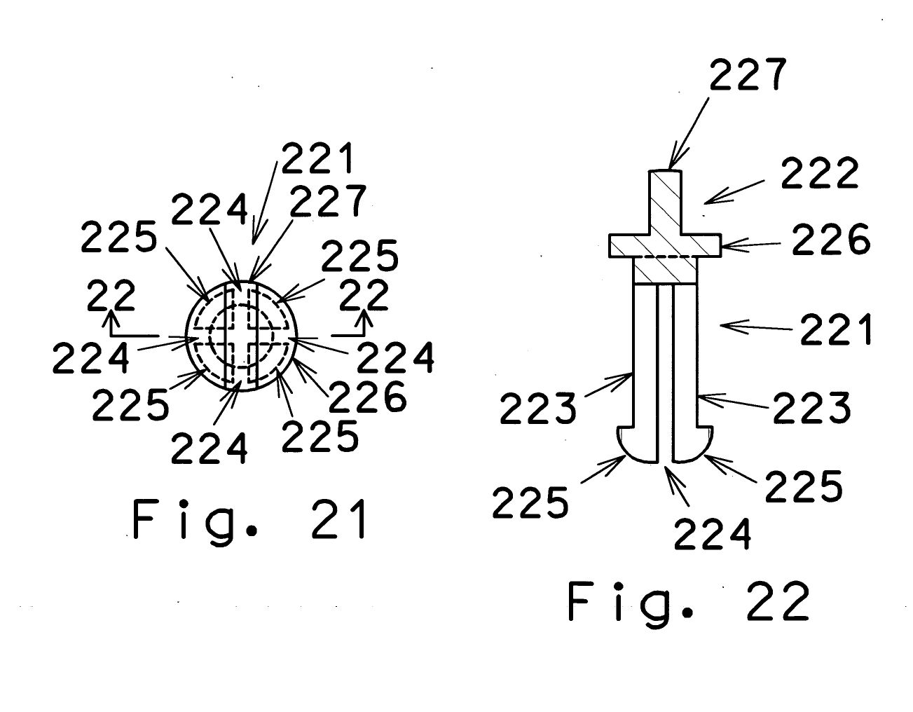

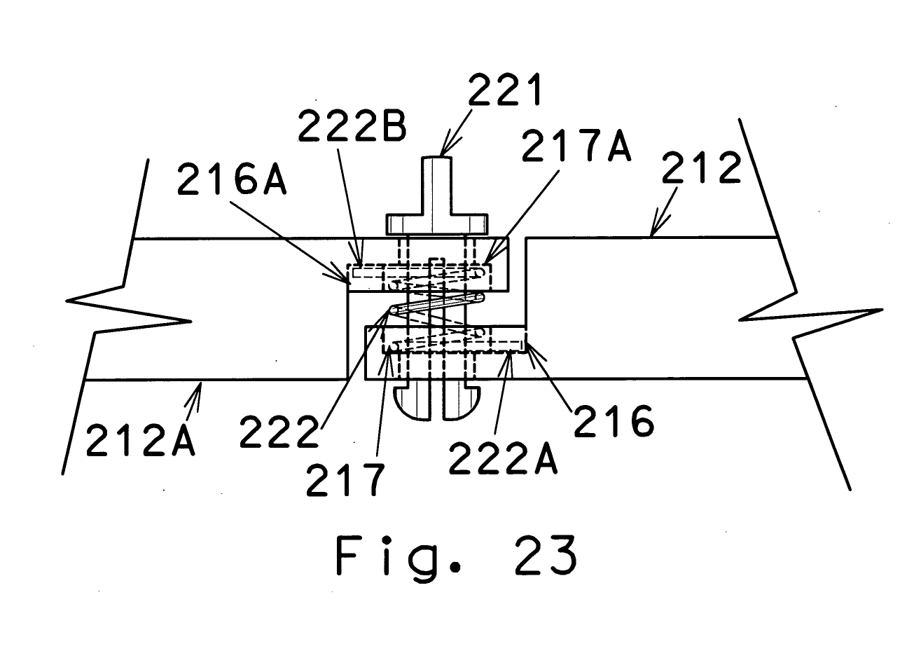

Referring to FIG. 21 and FIG. 22, a linker pin 221 consists a head 222 and at least two legs 223 (four shown). The head has a head plate 226 which is a plate and which has a handle 227 protruding on one side and the legs on the other side. The leg has an enlarged end 225 at its free end. The slots 224 between the legs allow the legs to bend a little toward each other when needed.

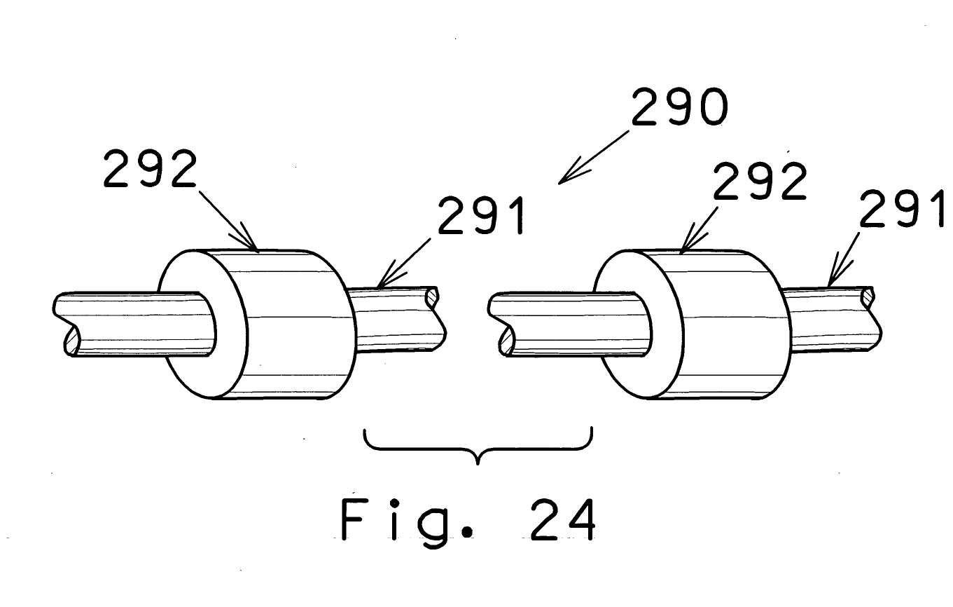

Referring to FIG. 23, a coiled spring 222 is put inside a coiled spring housing 217 of a linker unit 212 with an end of the coiled spring 222A in the coiled spring end slot 216. Another linker unit 212A is then put on this linker unit with the free end of the coiled spring 222B in the coiled spring end slot 216A and the coiled spring in the coiled spring housing 217A, both in the second linker unit. Then, a linker pin 221 is pushed into the eye of the 2nd linker unit, the center of the coiled spring, and the eye of the 1st linker unit. (Referring back to FIG. 22) The slots between the legs of the linker pin allow the enlarged ends of the linker pin to be pushed through the eyes. After passing through the eyes, the legs of the linker pin will straighten themselves back and the enlarged ends will prevent the linker pin to be pulled out of the eyes easily. The header plate of the linker pin and the enlarged ends of the legs of the linker pin will lock the two linker units together. In a similar way a linker pin can connect two linker units which connectors have no coiled spring housing or coiled spring end slot.

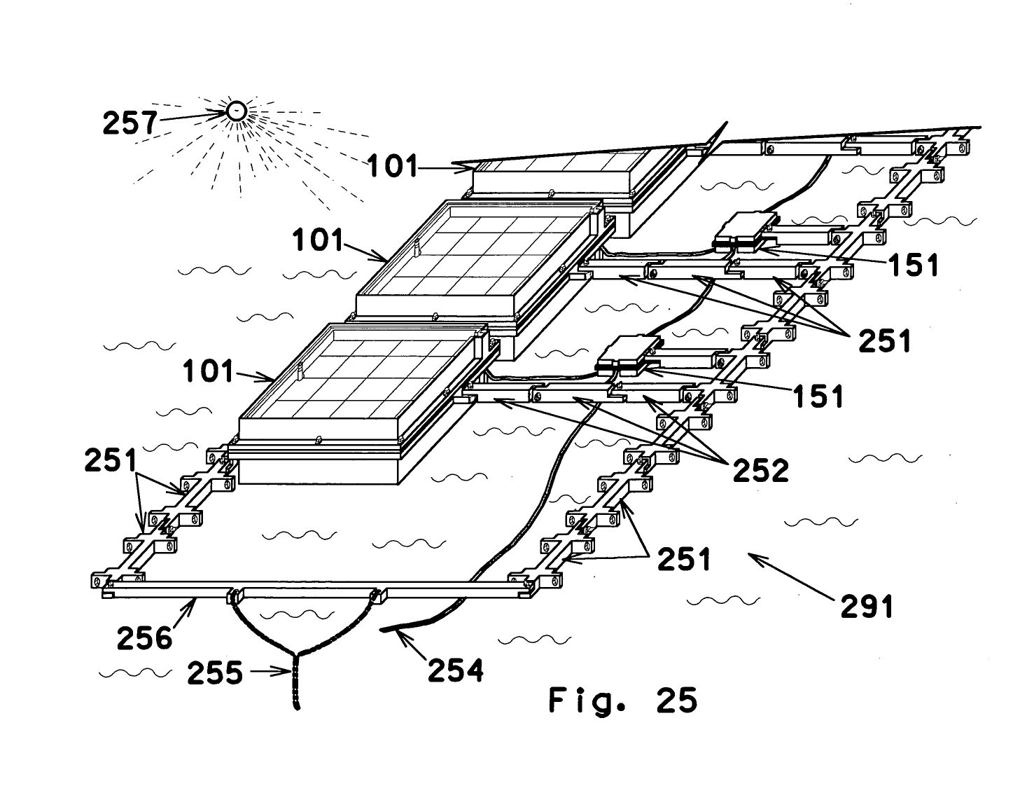

Referring to FIG. 24, a floatable power cable 290 consists numerous floats 292 mounted at intervals on an insulated cable 291 (conductors of the cable not shown). The floats can be made of any floatable material such as plastic.

The invented devices will be used on water surfaces. In using the invented devices, many floating solar power units will be linked together by the aforementioned linkers and the linker pins. Cables, ropes, and/or chains can also be used in lieu of the linkers and the linker pins. Floating cable boxes may also be used. The entire station could be used stationary or in motion. When stationary, anchors may be used. When in motion, boats or floats may be used. The following paragraphs will describe the uses of the invented devices in details. The terms or components in the Figs. cited in the following paragraphs maybe the same as those described previously although their referred numbers may be different.

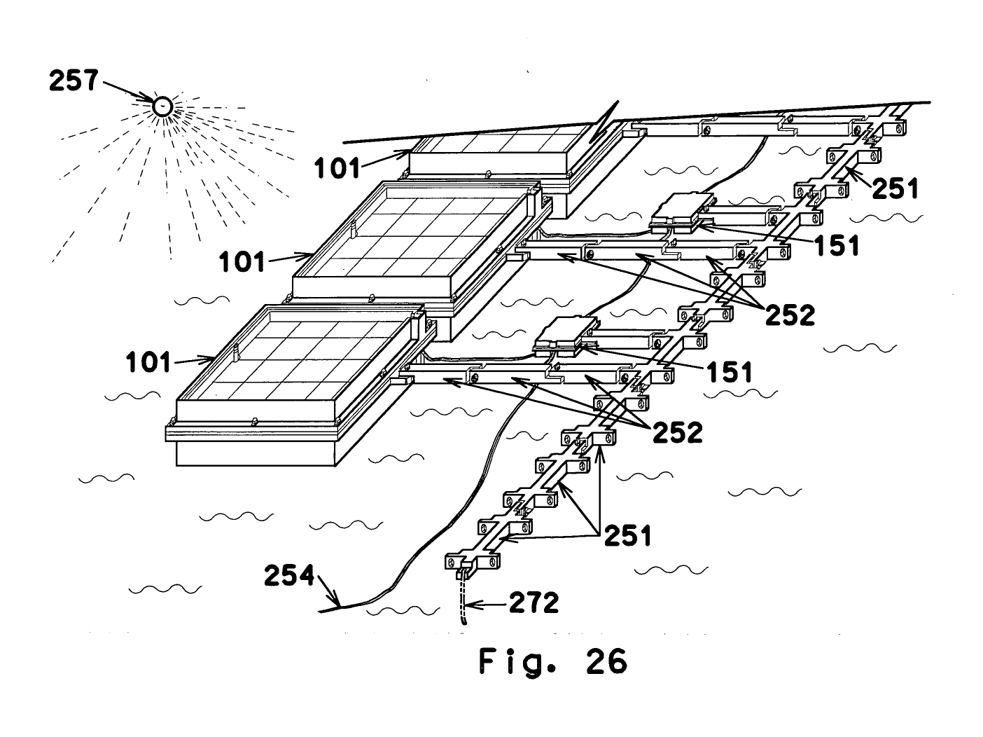

Referring to FIG. 25, many floating solar power collection units 101, many floating cable boxes 151 are linked together by linker units 251 and 252 (251 for linker A units; 252 for linker B units) to form a floating solar power station 191. The cables from the floating solar power collection units will join other cables in the floating cable boxes. The end of the cable 254 will then be extended to a location where the electricity is needed. When the sun 257 is up, the floating solar power collection units will generate electricity which will be sent through the cables for consumption. A special linker 256, which is a linker A unit, will link together the linker units on both sides of the floating solar power collection units. Anchor wires, chains, or ropes 255 will be connected to this special linker 256. An anchor (not shown) at the end of the anchor wire, chain or rope 255 will keep the assembly of the floating solar power station in a relatively stationary location.

Referring to FIG. 26, many floating solar power collection units 101, many floating cable boxes 151 are linked together by linker units 251 and 252 (251 for linker A units; 252 for linker B units) to form a floating solar power station 292. The cables from the floating solar power collection units will join other cables in the floating cable boxes. The end of the cable 254 will then be extended to a location where the electricity is needed. When the sun 257 is up, the floating solar power collection units will generate electricity which will be sent through the cables for consumption. Coiled springs are selectively inserted vertically in the connectors such that the coiled springs will keep the footprints of the entire station in a relatively stable original shape, after being temporarily distorted by winds or waves. An anchor wire, chain, or rope 272 will be connected to the end of an connector 251. An anchor (not shown) at the end of the anchor wire, chain or rope 272 will keep the assembly of the floating solar power station in a relatively stationary location.

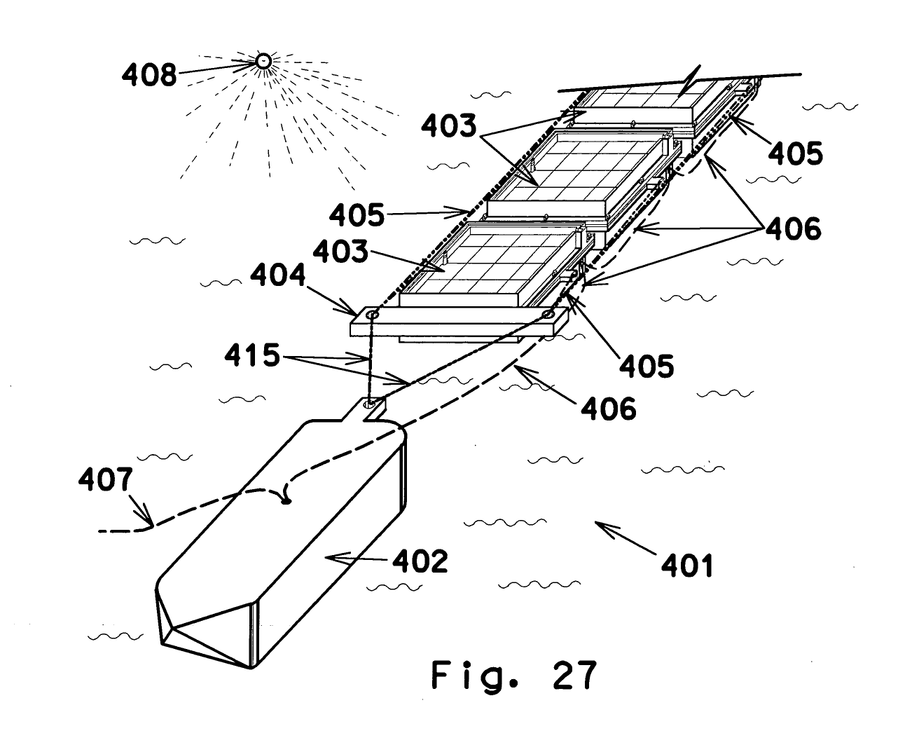

Referring to FIG. 27, a self-propelling solar boat unit 401 consists of an electrical power boat 402, many floating solar power collection units 403, a tow bar 404, many tow cables 405 and 415, an optional transmission cable 407, and many floating power cables 406. The floating solar power collection units are linked together by the tow cables 405 to form a floating solar power collection train. Each of the tow cables is connected to the tow bar 404 which is a bar which keeps the tow cables on each side of the train from squeezing the floating solar power collection units. Two other tow cables 415 link the tow bar to the electrical power boat 402 which is a boat and which has a motor, a propelling system which has at least a propeller, a rudder and a navigational and communicational device (all not shown). The floating power cables 406 connect each floating solar power collection unit to the electrical power boat. When needed, the optional transmission cable 407, which is a power cable, connects the electrical power boat to another power boat which will be described later. When the sun 408 is up, the floating solar power collection units will generate electricity which will be sent through the floating cables to the electrical power boat 402. The motor of the electrical power boat which takes the electricity will turn the propeller of the propelling system. The propeller will propel the entire self-propelling solar boat unit 401 forward. Electricity can also be sent through the transmission cable to the power boat (to be described in the following paragraph) when it is used. Floating cable box units can optionally be used in a self-propelling solar boat unit. In using the floating cable box units, one floating cable box unit can be placed between two floating solar power collection units.

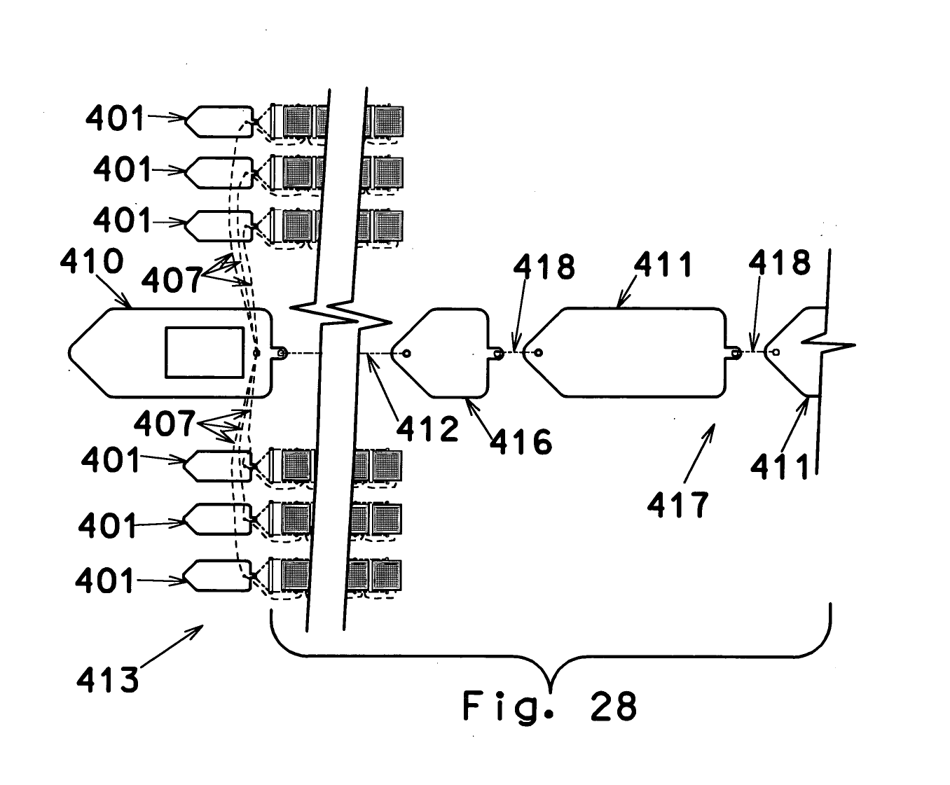

Referring to FIG. 28, a solar power cargo ship assembly 413 consists a power boat 410, a tow cable 412, a tow cable keeper 416, many cargo tow cables 418, many cargo units 411, and many self-propelling solar boat units 401 which are described in the previous paragraph. The tow cable, which is a chain, a rope, or a cable, connects the power boat 410 to the tow cable keeper 416 which is a float which can keep the end of the tow cable above water and which allows one end of a cargo cable 418, which is a chain, a rope, or a cable, to be connected to. Each of the cargo units 411 is a container which contains the cargo. The cargo tow cables link the cargo units to form a cargo train 417. The power boat 410 is a boat which has at least a motor, at least a propelling system which has at least a propeller, an electricity storage system which stores electricity, and other necessary facilities of a large boat such as dwelling facilities, communication facilities, control facilities, etc. The transmission cables 407 connect the power boat 410 with the self-propelling solar boat units 401. The transmission cables 407 transmit electricity, communications and control signals to and from the power boat and each of the self-propelling solar boat units. When the sun is up, each of the self-propelling solar boat units will collect electricity and will send some of the collected electricity to the power boat. The electricity will turn the propellers of the self-propelling solar boat units and the power boat. The communications among them will keep them moving synchronized. Any excessive electricity will be stored in the electricity storage system for uses when the sun is out. The moving of the power boat 410 will tug the tow cable 412 which in turn tugs the tow cable keeper 416 which in turn tugs the car go train 417. A solar power cargo ship assembly thus can transport cargo.

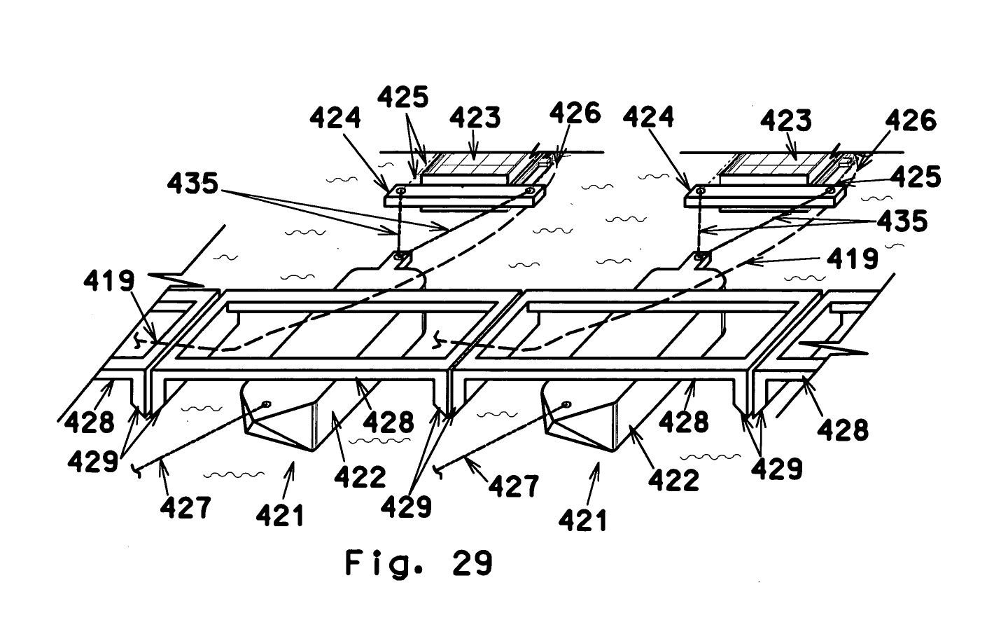

Referring to FIG. 29, each towed solar boat unit 421 consists a boat 422, many floating solar power collection units 423, a tow bar 424, many tow cables 425 and 435, a transmission cable 419, a tow cable 427, and many floating power cables 426. The floating solar power collection units are linked together by the tow cables, each of which is a chain, rope, or cable, to form a floating solar power collection train. Each of the tow cables 425, which is a chain, rope, or cable, is connected to the tow bar which is a bar which keeps the tow cables on each side of the train from squeezing the floating solar power collection units. Two other tow cables 435, each of which is a chain, rope, or cable, link the tow bar to the boat 422 which is a boat which has a unit spacer 428 which is a frame spanning and protruding sideways of the boat. The unit spacer has enlarged ends 429 at its ends. The distance between the enlarged ends of a unit spacer is wider than the tow bar. The function of the enlarged ends is to work with the enlarged ends of other unit spacers of other boats to keep the floating solar power collection trains from hitting each other. The floating power cables 426 connect each floating solar power collection units to the transmission cable 419 which is a power cable and which connects to an power boat which will be described later. When the sun is up, the floating solar power collection units will generate electricity which will be sent through the floating cables to the power boat to be described in the following paragraph. Floating cable box units can optionally be used in a towed solar boat unit. In using the floating cable box units, one floating cable box unit can be placed between two floating solar power collection units. The tow cable 427, which is a chain, rope, or cable, connects the boat 422 to the power boat.

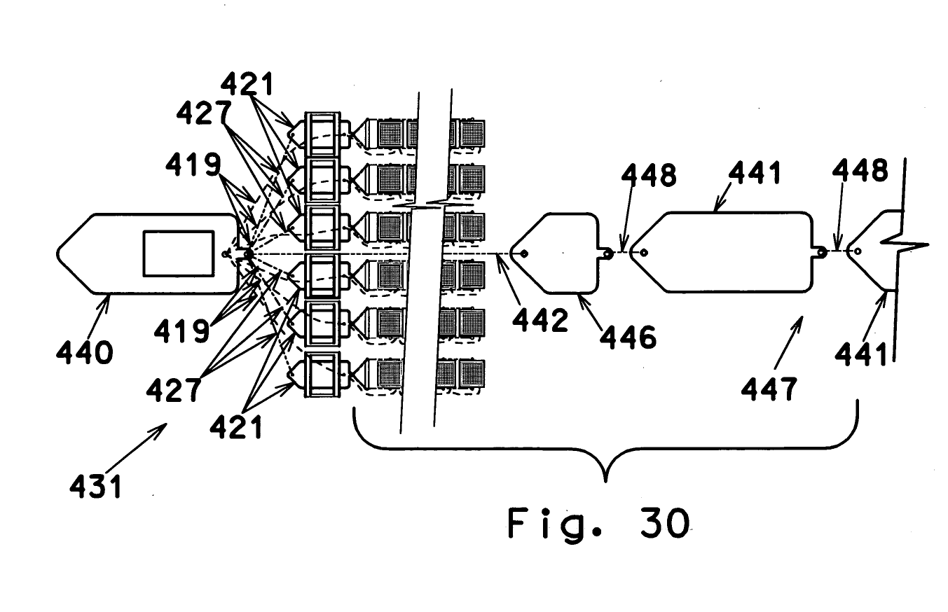

Referring to FIG. 30, a solar power cargo ship assembly 431 consists of a power boat 440, a tow cable 442, a tow cable keeper 446, many cargo tow cables 448, many cargo units 441, and many towed solar boat units 421 which are described in the previous paragraph. The tow cable, which is a chain, rope, or cable, connects the power boat 440 to the tow cable keeper 446 which is a float which can keep the end of the tow cable above water and which allows one end of a cargo cable 448, which is a chain, rope, or cable, to be connected to. Each of the cargo units 441 is a container which contains the cargo. Each of the cargo tow cable, which is a chain, rope, or cable, links the cargo units to form a cargo train 447. The power boat is a boat which has at least a motor, at least a propelling system which has at least a propeller, an electricity storage system which stores electricity, and other necessary facilities of a large boat such as dwelling facilities, communication facilities, control facilities, etc. Each of the tow cables 427 of each of the towed solar boat units 421 connects the towed solar boat unit to the power boat 440. Each of the transmission cables 419 of each of the towed solar boat units 421 is connected to the power boat 440. The transmission cables 419 transmit electricity, communications and control signals to and from the power boat and each of the towed solar boat units. When the sun is up, each of the towed solar boat units will collect electricity and will send the collected electricity to the power boat. The electricity will turn the propellers of the power boat which will tug the towed solar boat units. Any excessive electricity will be stored in the electricity storage system for uses when the sun is out. The moving of the power boat 440 will also tug the tow cable 442 which in turn tugs the tow cable keeper 446 which in turn tugs the car go train 447. A solar power cargo ship assembly thus can transport cargo.

Due to its size, a solar power cargo ship assembly will not enter a harbor. When the solar power cargo ship assembly nears its destination, only the cargo train or a cargo unit(s) will be dispatched from the assembly. New cargo train or cargo unit(s) will be picked up to be transported. Tugboats will handle the dispatched cargo train or cargo unit(s) locally.

The foregoing is considered as illustrative only of the principles of the invention. Furthermore, since numerous modifications and changes will readily occur to those skilled in the art, it is not desired to limit the invention to the exact construction and operation shown and described, and accordingly all suitable modifications and equivalents, may be resorted to, falling within the scope of the invention as claimed.

We claim:

1. A floating solar power collection unit consists a watertight floatable container which has a transparent top and which encloses a solar panel array which generated electricity can be conveyed to outside of said watertight floatable container; said watertight floatable container contains a flexible container which vents to air outside of said watertight floatable container to equalize air pressures inside and outside of said watertight floatable container; said watertight floatable container having a connection mean in plural form which can be used to connect said watertight floatable containers with other devices.

2. A floating cable box unit consists a watertight floatable container which allows a cable in plural form to enter and which allows said cable to be connected inside; said watertight floatable container contains a flexible container which vents to air outside of said watertight floatable container to equalize air pressures inside and outside of said watertight floatable container; said watertight floatable container having a connection mean in plural form which can be used to connect said watertight floatable containers with other devices.

3. A floating cable consists an insulated cable mounted with a float in plural form.

4. A floating linker system consist a linker in plural form, an optional coiled spring in plural form and a linker pin in plural form; said linker being a rod with an eye in plural form and being able to float on water surfaces; said coiled spring being able to be inserted into said eye; said linker pin being a pin which can engage with said eye and said coiled spring.

5. A floating solar power station consists an anchoring mean, a power conveying mean, and a floating solar power collection unit of claim 1 in plural form which are linked together by a floating linker system of claim 4 which is connected to said anchoring mean to anchor said floating solar power station in a relatively stationary location; said power conveying mean being able to collect and convey electricity generated by said floating solar power collection unit.

6. A floating solar power station of claim 5 of which said power conveying mean has the floating cable box unit of claim 2 in plural form.

7. A method to use solar power consists using a floating solar power station which is composed of linked together floating solar power collection units which float on a water surface; each of said floating solar power collection units containing a solar power panel array that can convert solar energy into electricity which can be conveyed away for consumption.

8. A method to use solar power consists using a floating solar power station which is composed of a boat and many linked together floating solar power collection units which are towed by said boat on a water surface; each of said floating solar power collection units contains a solar power panel array that can convert solar energy into electricity which can be sent for consumption and to said boat to be converted into propelling forces.

9. A self-propelling floating solar power station consists an electrical power boat, a power conveying mean, and a floating solar power collection unit of claim 1 in plural form which are linked together to form a train which is connected to said electrical power boat which can receive electricity and which can propel said self-propelling floating solar power station; said power conveying mean being able to collect and convey electricity generated by said floating solar power collection unit of claim 1 to said electrical power boat.

10. A self-propelling floating solar power station of claim 9 of which said power conveying mean has the floating cable box unit of claim 2 in plural form.

11. A towed floating solar power station consists a boat, a power conveying mean, and a floating solar power collection unit of claim 1 in plural form which are linked together to form a train which is connected to said boat which can be towed forward; said power conveying mean being able to collect and convey electricity generated by said floating solar power collection unit.

12. A towed floating solar power station of claim 11 of which said power conveying mean has the floating cable box unit of claim 2 in plural form.

13. A solar power ship assembly consists a power boat, a tow cable, a tow cable keeper, a self-propelling floating solar power station of claim 9 in plural form; said power boat being an electricity powered boat which can propel said solar power ship assembly; said tow cable keeper being a float; said tow cable being a link system which connects said tow cable keeper with said power boat; electricity collected by said self-propelling floating solar power station of claim 9 being able to be sent to said power boat.

14. A solar power ship assembly consists a power boat, a tow cable, a tow cable keeper, a self-propelling floating solar power station of claim 10 in plural form; said power boat being an electricity powered boat which can propel said solar power ship assembly; said tow cable keeper being a float; said tow cable being a link system which connects said tow cable keeper with said power boat; electricity collected by said self-propelling floating solar power station of claim 10 being able to be sent to said power boat.

15. A solar power ship assembly consists a power boat, a tow cable, a tow cable keeper, a towed floating solar power station of claim 11 in plural form; said power boat being an electricity powered boat which can propel said solar power ship assembly; said tow cable keeper being a float; said tow cable being a link system which connects said tow cable keeper with said power boat; electricity collected by said towed floating solar power station of claim 11 being able to be sent to said power boat.

16. A solar power ship assembly consists an power boat, a tow cable, a tow cable keeper, a towed floating solar power station of claim 12 in plural form; said power boat being an electricity powered boat which can propel said solar power ship assembly; said tow cable keeper being a float; said tow cable being a link system which connects said tow cable keeper with said power boat; electricity collected by said towed floating solar power station of claim 12 being able to be sent to said power boat.

17. A method to create a solar power ship assembly consists supplying and using electricity collected by many floating solar power stations to an electricity powered boat to tow a link system which links and tows a float which tows other floats.
